(19) United States
(12) Patent Application Publication
(10) Pub. No.: US 2025/0106998 A1
(43) Pub. Date: Mar. 27, 2025

(54) PRINTED WIRING BOARD, PRINTED CIRCUIT BOARD, ELECTRONIC EQUIPMENT, AND IMAGE FORMING APPARATUS

(71) Applicant: CANON KABUSHIKI KAISHA, Tokyo (JP)

(72) Inventors: TAKASHI NUMAGI, Tokyo (JP); HISAYUKI TAMURA, Kanagawa (JP)

(21) Appl. No.: 18/889,737

(22) Filed: Sep. 19, 2024

(30) Foreign Application Priority Data
Sep. 27, 2023 (JP) 2023-166283

(51) Int. Cl. H05K 1/11; H05K 1/18

(52) U.S. Cl. CPC H05K 1/116; H05K 1/181; H05K 2201/09227; H05K 2201/09254; H05K 2201/093; H05K 2201/09618; H05K 2201/10128; H05K 2201/10159; H05K 2201/10522; H05K 2201/10734

(57) ABSTRACT

A printed wiring board is aboard over which a first element having first signal terminals and a second element having second signal terminals are mountable, and comprises: first wirings, second wirings, and vias to electrically connect the first signal terminals and the second signal terminals, the first wirings and the second wirings are connected via the vias provided at intersections of the first wirings and the second wirings in a plan view viewed in a direction perpendicular to a main surface of the printed wiring board, an angle θ formed by the first wirings and the second wirings in the plan view is greater than 90° and less than 180°, and an angle φ formed by a first straight line passing through centers of the vias adjacent to each other and a second straight line passing through the first wiring in the plan view is arctan(sin θ).

### BACKGROUND

### Field

The present disclosure relates to a printed wiring board, a printed circuit board, electronic equipment, and an image forming apparatus.

### Description of the Related Art

High performance electronic equipment requires high speed processing of large amounts of data. Electronic equipment described in Japanese Patent Application Laid-Open No. 2014-16867 includes two memory devices to make it possible to process large amounts of data. The two memory devices described in Japanese Patent Application Laid-Open No. 2014-16867 are electrically connected to a memory controller by bus wirings constituted by fly-by-wire.

### SUMMARY

According to one aspect of the present disclosure, there is provided a printed wiring board over which a first element having a plurality of first signal terminals and a second element having a plurality of second signal terminals are mountable, the printed wiring board including: a plurality of first wirings, a plurality of second wirings, and a plurality of vias, the plurality of first wirings, the plurality of second wirings, and the plurality of vias being provided to electrically connect the plurality of first signal terminals and the plurality of second signal terminals, wherein the plurality of first wirings and the plurality of second wirings are connected via the plurality of vias provided at intersections of the plurality of first wirings and the plurality of second wirings in a plan view viewed in a direction perpendicular to a main surface of the printed wiring board, wherein an angle θ formed by the plurality of first wirings and the plurality of second wirings in the plan view, which is on a side closer to the first element and the second element, is greater than 90° and less than 180°, and wherein an angle φ formed by a first straight line passing through centers of the vias adjacent to each other and a second straight line passing through the first wiring in the plan view, which is on the same side as the angle θ relative to the second straight line, is arctan(sin θ).

According to another aspect of the present disclosure, there is provided a printed circuit board including: a first element having a plurality of first signal terminals; a second element having a plurality of second signal terminals; and a printed wiring board over which the first element and the second element are mounted, wherein the printed wiring board includes a plurality of first wirings, a plurality of second wirings, and a plurality of vias, the plurality of first wirings, the plurality of second wirings, and the plurality of vias being electrically connecting the plurality of first signal terminals and the plurality of second signal terminals, wherein the plurality of first wirings and the plurality of second wirings are connected via the plurality of vias provided at intersections of the plurality of first wirings and the plurality of second wirings in a plan view viewed in a direction perpendicular to a main surface of the printed wiring board, wherein an angle θ formed by the plurality of first wirings and the plurality of second wirings in the plan view, which is on a side closer to the first element and the second element, is greater than 90° and less than 180°, and wherein an angle φ formed by a first straight line passing through centers of the vias adjacent to each other and a second straight line passing through the first wiring in the plan view, which is on the same side as the angle θ relative to the second straight line, is arctan(sin θ).

Further features of the present disclosure will become apparent from the following description of exemplary embodiments with reference to the attached drawings.

### BRIEF DESCRIPTION OF THE DRAWINGS

FIG. 1 is a perspective view illustrating an image forming apparatus as an example of electronic equipment according to an embodiment.

FIG. 2 is a plan view illustrating a control module according to the embodiment.

FIG. 3 is a cross-sectional view illustrating a control module according to the embodiment.

FIG. 4 is a plan view illustrating a memory device according to the embodiment.

FIG. 5 is a plan view illustrating a command/address signal wiring according to the embodiment.

FIG. 6 is a plan view illustrating a region R1 including the command/address signal wiring and its periphery according to the embodiment.

FIG. 7 is a plan view illustrating a command/address signal wiring of Example 1.

FIG. 8 is a plan view illustrating an arrangement position of the ground via of Example 1.

FIG. 9 is a plan view illustrating a command/address signal wiring of

### Example 2.

FIG. 10 is a plan view illustrating a command/address signal wiring of Comparative Example.

### DESCRIPTION OF THE EMBODIMENTS

A memory system as an example of a printed circuit board includes: a memory controller having a plurality of transmitting terminals; a memory device having a plurality of receiving terminals; and a printed wiring board with the memory controller and the memory device mounted thereon. The transmitting terminals of the memory controller and the receiving terminals of the memory device are electrically connected by bus wirings of the printed circuit board. The memory controller controls the memory device by transmitting command signals and address signals to the memory device via the bus wirings. The memory controller and the memory device have data terminals for transmitting and receiving data signals, and the data terminals of the memory controller and the data terminals of the memory device are electrically connected by data signal wirings of the printed wiring board.

In order to process large amounts of data at high speed, the communication speed of the memory interface is increased. The memory interface operates in synchronization with a clock signal. As the frequency of the clock signal increases due to the increase in the speed, the period of the clock signal decreases. The address signal is operated in synchronization with this clock signal. Therefore, in order to realize the increase in the communication speed in the memory interface, it is required to reduce the time variation in which the address signals are received by the memory device.

For high-frequency signals having a transfer speed of more than 1 Gbps, the loss of an electrical signal increases when the wiring is long. The amplitude voltage drops and the rise and fall times of the signal waveform become longer due to the loss, and as a result, when the voltage noise margin and the timing margin decrease, the increase in the speed is inhibited. Therefore, in order to realize the increase in the speed, it is required to shorten the wirings in order to reduce the loss of the electrical signal caused by the wirings.

However, in the conventional printed wiring board, the first wiring drawn from the memory controller and the second wiring drawn to the memory device are arranged so that the two wirings are orthogonal to each other. Further, a via is arranged at the intersection of the first wiring and the second wiring, and the first wiring and the second wiring are connected via the via. In such a bus wiring structure, the wiring length variation can be reduced, but the wirings become longer.

For example, in order to shorten the wirings, a wiring structure in which the interval of the second wirings is narrowed can be considered. In this structure, the wiring can be shortened, but since the variation in the length of the wiring, that is, the variation in time, increases, the increase in the speed is inhibited. Further, when the length is shortened by making the angle formed between the first wiring and the second wiring 45 degrees, since the via and the wiring interfere, the wiring must be bypassed, and the variation in the length of the wiring increases, thereby inhibiting the increase in the speed. Thus, there is a trade-off between the variation in the length of the wiring and the wiring length.

Therefore, it is an object of the present disclosure to provide a printed wiring board and a printed circuit board which can realize the increase in the speed of a memory interface.

### One Embodiment

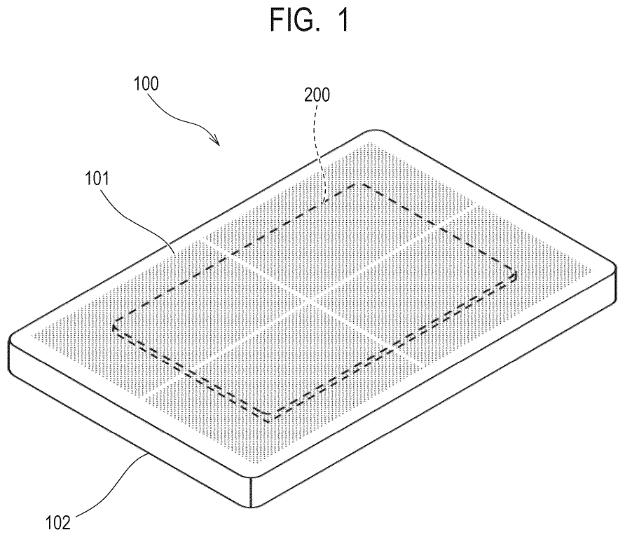

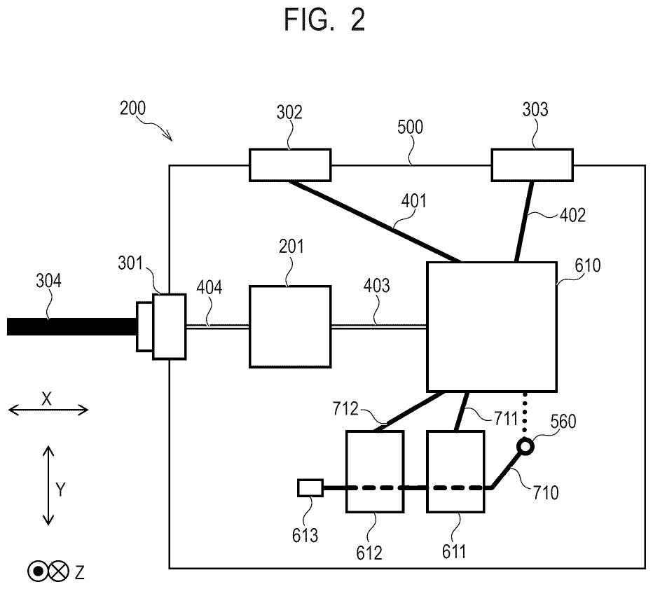

A printed wiring board and electronic equipment according to an embodiment of the present disclosure will be described with reference to FIG. 1 to FIG. 6. In the present embodiment, an image forming apparatus will be described as an example of electronic equipment.

FIG. 1 is a perspective view illustrating an image forming apparatus as an example of electronic equipment according to the present embodiment. The image forming apparatus 100 is not particularly limited, but is digital equipment such as an X-ray flat panel detector.

As illustrated in FIG. 1, the image forming apparatus 100 includes an apparatus body 101, a control module 200 that controls the apparatus body 101, and a housing 102. The control module 200 is provided on the back surface of the apparatus body 101 and is arranged in the housing 102 together with the apparatus body 101. The apparatus body 101 is a body unit that outputs image data corresponding to electromagnetic waves such as X-ray incident on the apparatus body 101 and includes a scintillator, a photodiode, a thin film transistor array, an analog digital converter, a low noise amplifier and the like (not illustrated).

The control module 200 is an electronic module as a printed circuit board. The control module 200 is connected to the apparatus body 101 so as to control the apparatus body 101. Image data output from the apparatus body 101 is input to the control module 200. The control module 200 performs image processing on the input image data. Further, the control module 200 transmits image data to external equipment via an interface such as a LAN (Local Area Network), a USB (Universal Serial Bus), or the like.

FIG. 2 is an explanatory view of the control module 200 according to the present embodiment. As illustrated in FIG. 2, the control module 200 includes a memory controller 610 as an example of a first element, a memory device 611 as an example of a second element, and a memory device 612 as an example of a third element. The control module 200 also includes a connector 301, a connector 302, a connector 303, a conversion chip 201, a resistor 613, and a printed wiring board 500. The memory device 611, the memory device 612, the memory controller 610, the connector 301, the connector 302, the connector 303, the conversion chip 201, and the resistor 613 are mounted on the printed wiring board 500. The printed wiring board 500 is, for example, a rigid board. The printed wiring board 500 includes a wiring 401, a wiring 402, a wiring 403, a wiring 404, a command/address signal wiring 710, and data signal wirings 711 and 712.

The memory device 611 and the memory device 612 are the same kind of memory devices. The memory devices 611 and 612 are memories of, for example, DDR (Double Data Rate) 4. Note that the memory devices 611 and 612 are not limited to the memories of DDR4 but may be memories of another standard or another type.

The apparatus body 101 is connected to the connectors 302 and 303 via cables (not illustrated). The connectors 302 and 303 receive image data from the apparatus body 101 via the cables. The connectors 302 and 303 are electrically connected to the memory controller 610 via the wirings 401 and 402 of the printed wiring board 500. The image data input to the connectors 302 and 303 is transmitted to the memory controller 610 via the wirings 401 and 402.

The memory controller 610 stores the image data in the memory devices 611 and 612 and reads the image data stored in the memory devices 611 and 612. The memory controller 610 is electrically connected to the conversion chip 201 via the wiring 403 of the printed wiring board 500. The memory controller 610 transmits the processed image data to the conversion chip 201 via the wiring 403.

The conversion chip 201 is electrically connected to the connector 301 via the wiring 404 of the printed wiring board 500. A cable 304 is connected to the connector 301. The conversion chip 201 converts the image data transmitted from the memory controller 610 to a format defined in the communication standard. Further, the conversion chip 201 outputs the converted image data to the cable 304 via the wiring 404 and the connector 301. The cable 304 is connected to, for example, a computer that displays images. The image data is inputted to the computer via the cable 304, and is subjected to processing in the computer, such as display processing on a display, storage processing in a storage device, or the like.

Each of the memory controller 610 and the memory devices 611 and 612 are composed of one semiconductor package. Each of the memory devices 611 and 612 and the memory controller 610 are electrically connected to each other via data signal wiring 711 and 712 of the printed circuit board 500 that serves as transmission paths for data signals representing image data. Each of the data signal wirings 711 and 712 is a bus wiring comprising a plurality of wirings.

Further, the memory controller 610 and the memory devices 611 and 612 are electrically connected to each other by a command/address signal wiring 710 of the printed wiring board 500 that serves as transmission lines for command signals and address signals. The command/address signal wiring 710 is a bus wiring comprising a plurality of signal wirings. The memory controller 610 transmits the command signals and the address signals to the two memory devices 611 and 612 via the command/address signal wiring 710 by a parallel transmission method. The command signals and the address signals, which are parallel signals transmitted from the memory controller 610, are both received by the two memory devices 611 and 612 via the command/address signal wiring 710. The memory controller 610 controls the memory devices 611 and 612 by transmitting the command signals and the address signals to the memory devices 611 and 612 via the command/address signal wiring 710. Each of the memory devices 611 and 612 performs processing such as storing and erasing image data in accordance with the command signals and the address signals.

As described above, the memory system is constituted by the memory controller 610, the memory devices 611 and 612, and the printed wiring board 500. The memory system is constituted as a printed circuit board.

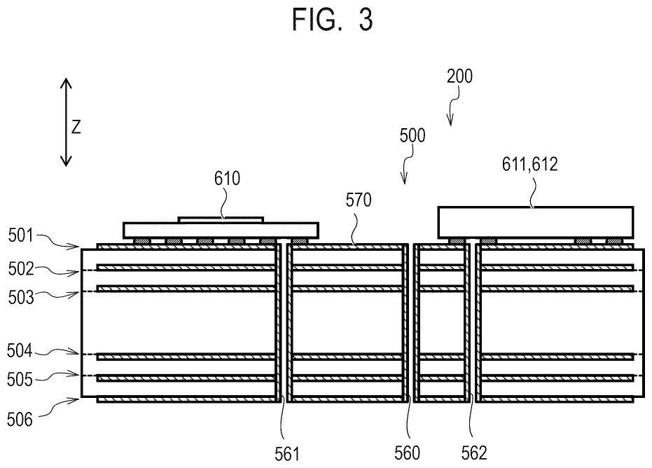

FIG. 3 is a cross-sectional view illustrating the control module 200 according to the present embodiment. The printed wiring board 500 has a base material having insulating properties and conductors having electrical conductivity and constituting wirings. The wirings are provided on or in the base material. The material of the base material is, for example, glass epoxy resin. The material of the conductor is, for example, copper. The printed wiring board 500 is a board on or over which the memory controller 610 and the memory devices 611 and 612 are mountable, and the memory controller 610 and the memory devices 611 and 612 are mounted on the printed wiring board 500. Note that the printed wiring board 500 is a board on or over which other components other than the memory controller 610 and the memory devices 611 and 612 are mountable, and other components may be mounted on or over the printed wiring board 500.

The printed wiring board 500 is a laminated substrate having a plurality of, for example, six conductor layers 501, 502, 503, 504, 505, and 506. The conductor layers 501 to 506 are spaced apart from each other in a Z direction which is perpendicular to the main surface of the printed wiring board 500 and which is also a lamination direction. Note that the base material, that is, insulating layers, are provided between the conductor layers 501 to 506. The conductor layers 501 to 506 are arranged in the order of the conductor layer 501, the conductor layer 502, the conductor layer 503, the conductor layer 504, the conductor layer 505, and the conductor layer 506 from one to the other in the Z direction. The conductor layers 501 and 506 are surface layers, which are mounting surface on which the memory controller 610, the memory devices 611 and 612, and the like can be mounted. The conductor layers 502 to 505 between the conductor layer 501 and the conductor layer 506 are inner layers. Note that protective films such as solder resists (not illustrated) may be provided on the conductor layers 501 and 506.

A conductor pattern 570 which is a conductor film constituting a wiring is formed in each of the conductor layers 501 to 506. Via conductors 560, 561, and 562 constituting wirings are arranged across the conductor layers 501 to 506. The via conductors 560, 561, and 562 are conductors formed in vias of the base material. In the present embodiment, the vias are through holes (through vias), and the via conductors 560, 561, and 562 are provided in the through holes.

Note that FIG. 3 is not an accurate illustration of the data signal wirings 711 and 712 and the command/address signal wiring 710 illustrated in FIG. 2, but is a schematic illustration of a cross section of the printed wiring board 500 for explaining the conductor layers 501 to 506.

The memory controller 610 and the memory devices 611 and 612 are mounted together on one conductor layer 501 of the conductive layers 501 and 506, which are the pair of the surface layers. Components such as capacitors, resistors, and the like (not illustrated) are mounted on the conductor layer 501 and 506. Conductor patterns that mainly function as grounds are formed in the conductor layers 502 and 505 respectively adjacent to the conductor layers 501 and 506 via the insulating layers. The conductor layer 501 is a third conductor layer. The conductor layer 503 is a first conductor layer. The conductor layer 504 is a second conductor layer. The conductor layer 503 is closer to the conductor layer 501 relative to the conductor layer 504. The conductor layers 503 and 504 are formed with conductor patterns that are mainly a part of wirings such as the data signal wirings 711 and 712, the command/address signal wiring 710, and the like.

The memory controller 610 and the memory devices 611 and 612 are jointed to the printed wiring board 500 by solder. The memory controller 610 and the memory devices 611 and 612 each have a plurality of signal terminals, a plurality of power terminals and a plurality of ground terminals. For example, sixteen of the plurality of signal terminals are data terminals. The structure of the terminals of the memory controller 610 and the memory devices 611 and 612 is, for example, BGA (Ball Grid Array).

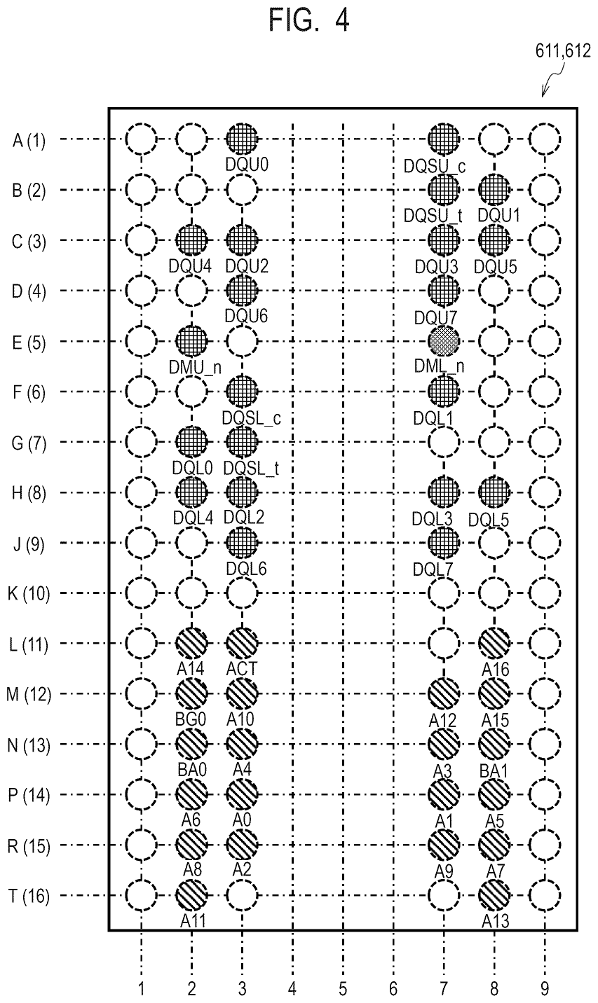

The arrangement of terminals in the memory devices 611 and 612 is illustrated in FIG. 4. FIG. 4 is a plan view illustrating the memory devices 611 and 612. FIG. 4 illustrates a view of the memory devices 611 and 612 as viewed from a side opposite to the side where the terminals are arranged. In FIG. 4, each terminal is represented by a dashed line as a hidden line.

The memory devices 611 and 612 are of DDR4-SDRAM. As illustrated in FIG. 4, the terminals are provided in columns 1 to 3 and columns 7 to 9 out of 16 rows×9 columns. The terminals are not provided in columns 4 to 6. The total number of the terminals is 96.

In FIG. 4, among the plurality of terminals, the shaded terminals are command/address terminals A0 to A16, BA0, BA1, BG0, and ACT. The command/address terminals A0 to A16, BA0, BA1, BG0, and ACT are arranged in rows 11 to 16 and columns 2 to 8. The terminals illustrated in mesh are data terminals DQU0 to DQU7, data mask terminal DMU_n, data strobe terminals DQSU_c and DQSU_t, data terminals DQL0 to DQL7, data mask terminal DML_n, data strobe terminals DQSL_c and DQSL_t. These data terminals, data mask terminals, and data strobe terminals are arranged in rows 1 to 9 and columns 2 to 8.

Generally, the memory devices 611 and 612 are arranged so that the data terminals of the memory devices 611 and 612 are directed toward the side of the memory controller 610. The data terminals of the memory devices 611 and 612 and the data terminals of the memory controller 610 are electrically connected to each other via the data signal wirings 711 and 712.

The command/address terminals of the memory devices 611 and 612 are arranged far from the memory controller 610. The command/address signal wiring 710 is a fly-by-wire structure comprising a plurality of wirings that function as a plurality of signal wirings. The command/address terminals of the memory devices 611 and 612 and the command/address terminal of the memory controller 610 are electrically connected to each other by the command/address signal wiring 710. One end of the command/address signal wiring 710 is connected to the resistor 613. The resistor 613 is a termination element and a chip resistor that is connected to a termination voltage in a pull-up manner. As illustrated in FIG. 2, the command/address signal wiring 710 is connected to the memory devices 611 and 612 with L-shaped wiring.

The memory interface operates in synchronization with a clock signal. As the frequency of the clock signal increases due to the increase in the speed, the period of the clock signal decreases. In order to realize the increase in the speed of the memory interface, it is necessary to reduce the variation in the time for the command/address signal output from the memory controller 610 to reach the memory devices 611 and 612. For example, the period of the address signal of the DDR3-800 memory interface is 2500 picoseconds. If the tolerance value of the variation of the arrival time is 10% of the period, the tolerance value is 250 picoseconds in time. When the wiring delay time of the 1 mm wiring is 7 picoseconds, the variation of the command/address signal wiring of about 35.7 mm is allowed. As the increase in the speed is advanced, the period of the address signal of the DDR4-3200 memory interface is 625 picoseconds. If the tolerance of the arrival time is 10% of the period, the tolerance is 62.5 picoseconds in time. In this case, the variation of the command/address signal wiring allowed is about 8.9 mm.

In order to realize a faster memory interface, it is required to suppress the variation of the length of a plurality of wirings constituting the command/address signal wiring to a small degree. In the arrangement of the command/address terminals of the memory devices 611 and 612 illustrated in FIG. 4, the terminal spacing is, for example, 0.8 mm. In this case, for example, a length variation of 4.8 mm occurs between the command/address terminal A5 in row 14 and column 8 and the command/address terminal A6 in row 14 and column 2. Therefore, when the terminal spacing is narrower as described above, the allowable length variation of the command/address signal wiring 710 connecting the memory controller 610 and the memory device 612 becomes smaller.

As a method for aligning the length of the command/address signal wiring, there is a meander wiring. The meander wiring is a wiring structure in which the length of a wiring is adjusted by lengthening the wiring by a structure that makes the wiring meander. When the lengths of wirings are aligned by using the meander wiring, the wirings become longer because the length of the bus wiring of the command/address signal is adjusted to match the longest signal wiring. As the memory interface becomes faster, the effect of frequency loss of the electrical signal caused by the wiring cannot be ignored. The frequency loss causes the drop of the amplitude voltage and the rise and fall times of the signal waveform to be longer, and the voltage noise margin and the timing margin decrease. Therefore, the increase in the wiring length hinders the increase in the speed of the memory interface. Therefore, in order to realize the increase in the speed of the memory interface, it is required to shorten the wirings in order to reduce the loss caused by the wirings.

Therefore, in the present embodiment, by devising the wiring structure of the command/address signal wiring 710, the variation in the lengths of the plurality of wirings constituting the command/address signal wiring 710 illustrated in FIG. 2 is reduced in a plan view in the Z direction, and the lengths of the wirings are shortened. Hereinafter, the wiring structure of the command/address signal wiring 710 in the control module 200 according to the present embodiment will be specifically described.

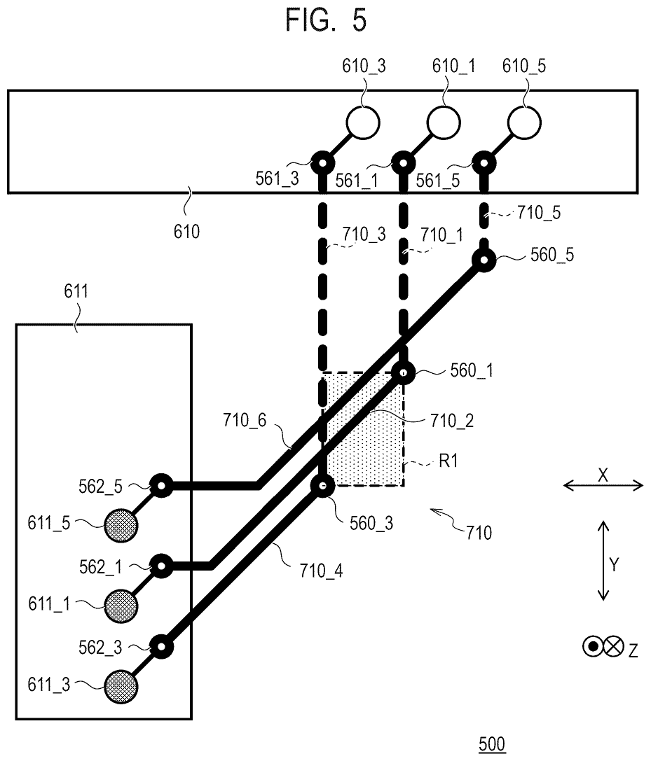

FIG. 5 is a plan view illustrating a part of the memory controller 610 and a part of the memory device 611 when the control module 200 according to the present embodiment is viewed in a plan view, that is, when viewed in the Z direction which is a direction perpendicular to the main surface of the printed wiring board 500. As illustrated in FIG. 5, the memory controller 610 is spaced on the printed wiring board 500 in the Y direction orthogonal to the X direction and the Z direction with respect to the memory device 611. Note that the X direction and the Y direction are parallel to the main surface of the printed wiring board 500. In order to simplify the description, a case where the command/address signal wiring 710 has three signal wirings as illustrated in FIG. 5 will be described below.

The memory controller 610 has a plurality of command/address terminals 610_1, 610_3, and 610_5 which are a plurality of control signal terminals. The command/address terminals 610_1, 610_3, and 610_5 are arranged so as to be arranged at predetermined intervals in the X direction. The memory device 611 has a plurality of command/address terminals 611_1, 611_3, and 611_5, which are a plurality of control signal terminals. The command/address terminals 611_1, 611_3, and 611_5 are arranged so as to be arranged at predetermined intervals in the Y direction.

The command/address terminal 610_1 of the memory controller 610 is electrically connected to the command/address terminal 611_1 of the memory device 611 via a via 561_1, a wiring 710_1, a via 560_1, a wiring 710_2, and a via 562_1. The via 561_1 is a via constituted by the via conductor 561, and electrically connects the command/address terminal 610_1 to the wiring 710_1. The via 560_1 is a via constituted by the via conductor 560, and electrically connects the wiring 710_1 to the wiring 710_2. The via 562_1 is a via constituted by the via conductor 562, and electrically connects the wiring 710_2 to the command/address terminal 611_1. The via 561_1, the wiring 710_1, the via 560_1, the wiring 710_2, and the via 562_1 constitute a wiring which functions as one of the signal wirings among the plurality of signal wirings in the command/address signal wiring 710.

The command/address terminal 610_3 of the memory controller 610 is electrically connected to the command/address terminal 611_3 of the memory device 611 via a via 561_3, a wiring 710_3, a via 560_3, a wiring 710_4, and a via 562_3. The via 561_3 is a via constituted by the via conductor 561, and electrically connects the command/address terminal 610_3 to the wiring 710_3. The via 560_3 is a via constituted by the via conductor 560, and electrically connects the wiring 710_3 to the wiring 710_4. The via 562_3 is a via constituted by the via conductor 562, and electrically connects the wiring 710_4 to the command/address terminal 611_3. The via 561_3, the wiring 710_3, the via 560_3, the wiring 710_4, and the via 562_3 constitute a wiring which functions as one of the signal wirings among the plurality of signal wirings in the command/address signal wiring 710.

The command/address terminal 610_5 of the memory controller 610 is electrically connected to the command/address terminal 611_5 of the memory device 611 via a via 561_5, a wiring 710_5, a via 560_5, a wiring 710_6, and a via 562_5. The via 561_5 is a via constituted by the via conductor 561, and electrically connects the command/address terminal 610_5 to the wiring 710_5. The via 560_5 is a via constituted by the via conductor 560, and electrically connects the wiring 710_5 to the wiring 710_6. The via 562_5 is a via constituted by the via conductor 562, and electrically connects the wiring 710_6 to the command/address terminal 611_5. The via 561_5, the wiring 710_5, the via 560_5, the wiring 710_6, and the via 562_5 constitute a wiring which functions as one of the signal wirings among the plurality of signal wirings in the command/address signal wiring 710.

Thus, the plurality of command/address terminals 610_1, 610_3, and 610_5 and the command/address terminals 611_1, 611_3, and 611_5 are electrically connected by the plurality of wirings and the plurality of vias provided for electrically connecting them. The wirings for electrically connecting includes the plurality of wirings 710_1, 710_3, and 710_5 and the plurality of wirings 710_2, 710_4, and 710_6. The vias for electrically connecting includes the via 560_1, the via 560_3, the via 560_5, the via 561_1, the via 561_3, the via 561_5 and the via 562_1, via 562_3, via 562_5. In a plan view of the printed wiring board 500 viewed in the Z direction, the via 560_1, the via 560_3, and the via 560_5 are provided at the intersections of the plurality of wirings 710_1, 710_3, and 710_5 and the plurality of wirings 710_2, 710_4, and 710_6, respectively. Also in a plan view viewed in the Z direction in the same manner, the plurality of wirings 710_1, 710_3, and 710_5 are arranged on the side of the memory controller 610 more than the plurality of wirings 710_2, 710_4, and 710_6 with respect to the via 560_1, the via 560_3, and the via 560_5.

Note that, in the present embodiment, a case where the plurality of wirings 710_1, 710_3, and 710_5 and the plurality of wirings 710_2, 710_4, and 710_6 are address bus wirings will be described, but the wirings are not limited thereto. The plurality of wirings 710_1, 710_3, and 710_5 and the plurality of wirings 710_2, 710_4, and 710_6 may be data bus wirings.

The plurality of wirings 710_1, 710_3, and 710_5 are formed in a conductor layer, such as the conductor layer 504, which is far from the surface layer of one surface of the printed circuit board 500 on which the memory controller 610 and the memory devices 611 and 612 are mounted. The plurality of wirings 710_2, 710_4, and 710_6 are formed in a conductor layer, such as the conductor layer 503, which is close to the surface layer of one surface of the printed circuit board 500 on which the memory controller 610 and the memory devices 611 and 612 are mounted. The conductor layer 504 is located further than the conductor layer 503 from the surface layer of one surface of the printed wiring board 500 on which the memory controller 610 and the memory devices 611 and 612 are mounted.

The conductor layer 502 is a ground layer located between the surface layer of one surface of the printed wiring board 500 on which the memory controller 610 and the memory devices 611 and 612 are mounted and the conductor layer 503. The conductor layer 505 is a ground layer located further than the conductor layer 504 from the surface layer of one surface of the printed wiring board 500 on which the memory controller 610 and the memory devices 611 and 612 are mounted.

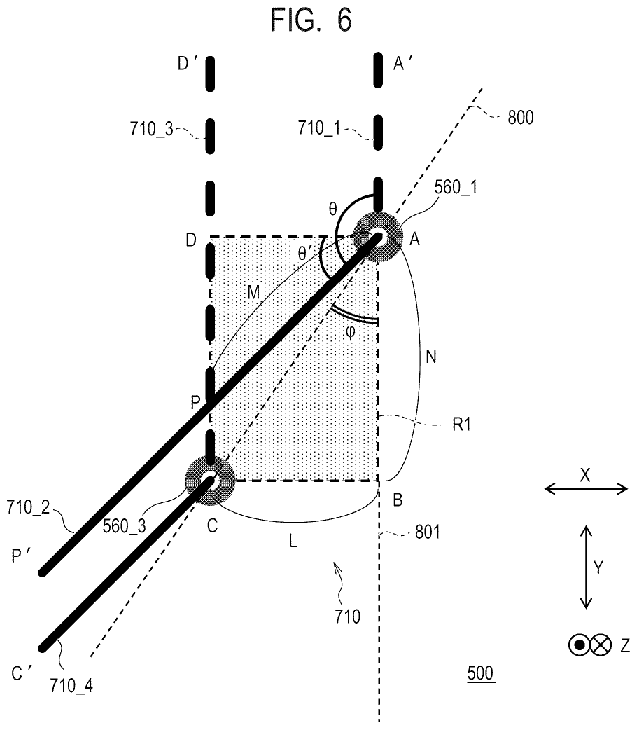

A region R1 illustrated in FIG. 5 is a rectangular region with the center of the via 560_1 and the center of the via 560_3 as vertices located diagonally opposite each other. Here, the intersecting angle of the wirings and the arrangement position of the vias which makes the variation in the lengths of the wirings constituting the command/address signal wiring 710 as the address bus wiring suppressed small will be described with reference to FIG. 6. FIG. 6 illustrates the region R1 and its periphery. In FIG. 6, symbols are provided to explain angles and the lengths of line segments.

The wiring 710_1 and the wiring 710_2 are connected via the via 560_1. The center of this via 560_1 is set to A. The wiring 710_3 and the wiring 710_4 are connected via the via 560_3. The center of this via 560_3 is set to C. The region R1 is a rectangle having the center A and the center C as vertices located diagonally opposite each other. In the region R1, the remaining vertices located diagonally opposite each other are designated as B and D. In the plan view viewed in the Z direction, the point where the wiring 710_2 and the wiring 710_3 intersect is designated as P. In the plan view viewed in the Z direction, the angle formed by the wiring 710_1 and the wiring 710_2 is designated as θ (theta). The angle θ is an angle on the side closer to the memory controller 610 and the memory device 611. In the plane view viewed in the Z direction, a straight line 800 is defined as a line passing through the centers of the vias 560_1 and 560_3 adjacent to each other, that is, the center A of the via 560_1 and the center C of the via 560_3. In the plan view viewed in the Z direction, a straight line 801 is defined as a straight line passing through the wiring 710_1 superimposed on the wiring 710_1. In the plan view viewed in the Z direction, an angle (_BAC) formed by the straight line 800 and the straight line 801 is defined as q (phi). The angle φ is an angle on the same side as the angle θ with respect to the straight line 801 in the plan view viewed in the Z direction.

A case in which the wirings outside the region R1 are of the same length is considered. That is, the line segment AA′ and the line segment DD′ have the same length, and the line segment CC′ and the line segment PP′ have the same length. Here, the point A′ is a point closer to the side of the memory controller 610 than the center A (vertex A) on the wiring 710_1 in the plan view viewed in the Z direction. The point D′ is a point closer to the side of the memory controller 610 than the vertex D on the wiring 710_3 in the plan view viewed in the Z direction. The points A′ and D′ have equal positions in the Y direction. The point C′ is a point closer to the side of the memory device 611 than the center C (vertex C) on the wiring 710_4 in the plan view viewed in the Z direction. The point P′ is a point closer to the side of the memory device 611 than the point P on the wiring 710_4 in the plane view viewed in the Z direction. In order for the length of the wiring A′P′ (the line segment A′A+the line segment AP+the line segment PP′) and the length of the wiring D′C′ (the line segment D′D+the line segment DP+the line segment PC+the line segment CC′) to be equal to each other, the line segment AP and the line segment DC need to be equal in length to each other. Here, the length of the line segment CB is represented by L, the length of the line segment AP is represented by M, and the length of the line segment AB is represented by N. The length M of the line segment AP is obtained by the following expression (1).

$$M = \frac{L}{sin θ} \qquad ( 1 )$$

Here, the range of θ is 90°<θ<180°. Note that, since the angle θ is φA′AP and ∠DAP=θ′=θ−90°, these give L=M×cos θ′=M×cos(θ−90°)=M×sin θ, which is solved for M to obtain the expression (1).

Since the length of the line segment AP and the length of the line segment DC are equal to each other, the length N of the line segment AB is obtained by the following expression (2).

$$M = N = \frac{L}{sin θ} \qquad ( 2 )$$

With respect to the via 560_1, a position where via 560_3 is arranged is a position moved by N=L/sine in the Y direction and moved by L in the X direction. At this time, when the angle (∠BAC) formed by the straight line 800 passing through the center A of the via 560_1 and the center C of the via 560_3 and the wiring 710_1 is assumed to be φ, the angle φ satisfies the relational expression.

$$tan ϕ = \frac{L}{N} = \frac{L}{\frac{L}{sin θ}} = sin θ$$

When the above relational expression is solved for the angle φ, the angle φ is obtained by the following expression (3).

$$ϕ = arctan ( sin θ ) \qquad ( 3 )$$

Here, the angle φ is an acute angle, and the range of the angle φ is 0°<φ<<90°.

As described above, when the wiring 710_1 and the wiring 710_2 intersect at the angle θ in the plane view of the printed wiring board 500 viewed in the Z direction, the via 560_3 is arranged so that the angle φ formed by the straight line 800 and the wiring 710_1 is arctan(sin θ). Note that the via 560_3 is arranged at the position where the straight line 800 and the wiring 710_3 intersect in the above plane view. By connecting the wiring 710_3 to the wiring 710_4 via the via 560_3 thus arranged, the length variation of the plurality of wirings constituting the command/address signal wiring 710 can be suppressed to a small extent, and the command/address bus wiring structure having a short wiring length can be realized. According to the present embodiment, it is possible to realize the increase in the speed of the memory interface.

As described above, according to the present embodiment, the variation in the length of the command/address bus wiring can be suppressed to a small extent, and the command/address bus wiring structure having a short wiring length can be realized, and thus the increase in the speed of the memory interface can be realized.

Note that, although the image forming apparatus 100 has been described as an example of the electronic equipment in the present embodiment, the electronic equipment according to the present embodiment is not limited to the image forming apparatus 100. The electronic equipment may be any equipment that uses a printed circuit board including a printed wiring board having a wiring structure similar to that of the printed wiring board 500.

### EXAMPLES

A more specific configuration of the printed circuit board 500 according to the present embodiment will be described with reference to Example 1, Example 2, and Comparative Example.

### Example 1

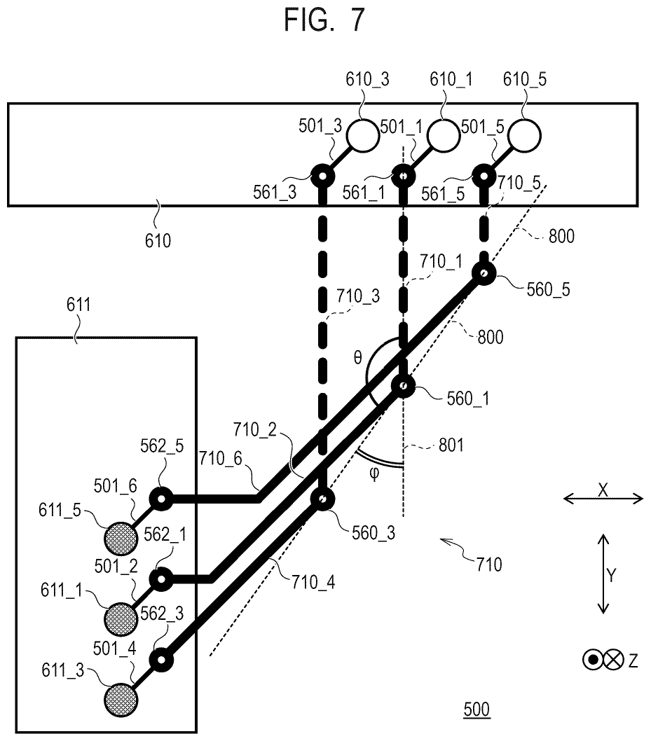

FIG. 7 is a plan view illustrating the command/address signal wiring 710 of Example 1 when viewed in the Z direction. The memory controller 610 has the command/address terminals 610_1, 610_3, and 610_5. The memory device 611 has the command/address terminals 611_1, 611_3, and 611_5.

The command/address terminal 610_1 of the memory controller 610 and the command/address terminal 611_1 of the memory device 611 are electrically connected by the wirings of the printed wiring board 500. More specifically, the command/address terminal 610_1 and the via 561_1 are connected by the wiring 501_1 formed in the conductor layer 501. The via 561_1 and the via 560_1 are connected by the wiring 710_1 formed in the conductor layer 504. The conductor layer 505 is a ground layer. The via 560_1 and the via 562_1 are connected by the wiring 710_2 formed in the conductor layer 503. The conductor layer 502 is a ground layer. The via 562_1 and the command/address terminal 611_1 of the memory device 611 are connected by the wiring 501_2 formed in the conductor layer 501. The angle formed between the wiring 710_1 and the wiring 710_2 is θ (90°<θ<180°).

The command/address terminal 610_3 of the memory controller 610 and the command/address terminal 611_3 of the memory device 611 are electrically connected by the wirings of the printed wiring board 500. More specifically, the command/address terminal 610_3 and the via 561_3 are connected by the wiring 501_3 formed in the conductor layer 501. The via 561_3 and the via 560_3 are connected by the wiring 710_3 formed in the conductor layer 504. The via 560_3 and the via 562_3 are connected by the wiring 710_4 formed in the conductor layer 503. The via 562_3 and the command/address terminal 611_3 of the memory device 611 are connected by the wiring 501_4 formed in the conductor layer 501. The angle formed between the wiring 710_3 and the wiring 710_4 is θ (90°<θ<180°). The angle formed between the straight line 800 passing through the center of via 560_1 and the center of via 560_3 and the wiring 710_1 is φ.

When the angle θ is 135°, the angle φ is obtained by the expression (3) and is about 35°. If the distance between the wiring 710_1 and the wiring 710_3 in the X direction is 1 mm, the length M of the line segment AP illustrated in FIG. 6 is √2 mm. In order for the length M of the line segment AP to be equal to the length N of the line segment AB, the position of the via 560_3 is a position moved by √2 mm in the Y direction and 1 mm in the X direction with respect to the via 560_1. Thus, tan φ=L/M=1/√2, and φ≈35°.

The command/address terminal 610_5 of the memory controller 610 and the command/address terminal 611_5 of the memory device 611 are electrically connected by the wiring of the printed wiring board 500. More specifically, the command/address terminal 610_5 and the via 561_5 are connected by the wiring 501_5 formed in the conductor layer 501. The via 561_5 and the via 560_5 are connected by the wiring 710_5 formed in the conductor layer 504. The via 560_5 and the via 562_5 are connected by the wiring 710_6 formed in the conductor layer 503. The via 562_5 and the command/address terminal 611_5 of the memory device 611 are connected by the wiring 501_6 formed in the conductor layer 501. The angle formed between the wiring 710_5 and the wiring 710_6 is θ (90°<θ<180°).

Thus, in the plan view of the printed wiring board 500 viewed in the Z direction, the plurality of wirings 710_1, 710_3, and 710_5 and the plurality of wirings 710_2, 710_4, and 710_6 intersect each other at the angle θ greater than 90° and less than 180°. Note that the angle θ is preferably 135° from the viewpoint of shortening the wiring.

The wirings constituting the command/address signal wiring 710 is switched from the wirings 710_1, 710_3, and 710_5 of the conductor layer 504 to the wirings 710_2, 710_4, and 710_6 of the conductor layer 503 by the vias 560_1, 560_3, and 560_5. Accordingly, it is desirable that the ground serving as the return paths of the command/address signals is switched from the conductor layer 505 to the conductor layer 502. In this case, the conductor layer 502 serving as the ground layer and the conductor layer 505 serving as the ground layer are connected by the ground via 563 formed in the printed wiring board 500.

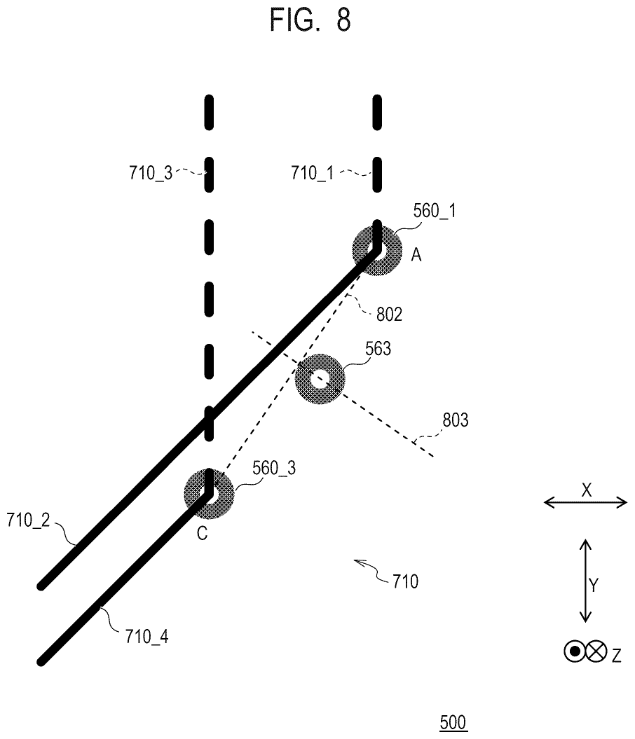

FIG. 8 is a plan view illustrating the arrangement position of the ground via 563. As illustrated in FIG. 8, the ground via 563 connecting the conductor layer 502 and the conductor layer 505 may be arranged at a position equal to from the via 560_1 and the via 560_3 in the command/address signal wiring 710 in the plan view viewed in the Z direction. Specifically, in the plan view viewed in the Z direction, the ground via 563 may be arranged at a position on the perpendicular bisector 803 with respect to the line segment 802 connecting the center A of the via 560_1 and the center C of the via 560_3, which are adjacent to each other.

### Comparative Example

FIG. 10 is a plan view illustrating a command/address signal wiring 710a of Comparative Example when viewed in the Z direction. The components of the Comparative Example will be described by adding “a” at the end of the numeral sign or before “_” of the corresponding component of Example 1. However, some components to which “a” is added are not illustrated. The memory controller 610a includes command/address terminals 610a_1, 610a_3, and 610a_5. The memory device 611a includes command/address terminals 611a_1, 611a_3, and 611a_5.

The command/address terminal 610a_1 of the memory controller 610a and the command/address terminal 611a_1 of the memory device 611a are electrically connected by wirings of a printed wiring board 500a. More specifically, the command/address terminal 610a_1 and a via 561a_1 are connected by a wiring 501a_1 formed in a conductor layer 501a. The via 561a_1 and a via 560a_1 are connected by a wiring 710a_1 formed in a conductor layer 504a. A conductor layer 505a is a ground layer. The via 560a_1 and a via 562a_1 are connected by a wiring 710a_2 formed in a conductor layer 503a. A conductor layer 502a is a ground layer. The via 562a_1 and the command/address terminal 611a_1 of the memory device 611a are connected by a wiring 501a_2 formed in the conductor layer 501a. The angle formed between the wiring 710a_1 and the wiring 710a_2 is 90°. The angle formed between a straight line 800a passing through the center of the via 560a_1 and the center of a via 560a_3 and a straight line 801a which overlaps the wiring the wiring 710a_1 and passes through the wiring 710a_1 is 45°.

The command/address terminal 610a_3 of the memory controller 610a and the command/address terminal 611a_3 of the memory device 611a are electrically connected by wirings of the printed wiring board 500a. More specifically, the command/address terminal 610a_3 and a via 561a_3 are connected by a wiring 501a_3 formed in the conductor layer 501a. The via 561a_3 and the via 560a_3 are connected by a wiring 710a_3 formed in the conductor layer 504a. The via 560a_3 and a via 562a_3 are connected by a wiring 710a_4 formed in the conductor layer 503a. The via 562a_3 and the command/address terminal 611a_3 of the memory device 611a are connected by a wiring 501a_4 formed in the conductor layer 501a. The angle formed between the wiring 710a_3 and the wiring 710a_4 is 90°.

The command/address terminal 610a_5 of the memory controller 610a and the command/address terminal 611a_5 of the memory device 611a are electrically connected by wirings of the printed wiring board 500a. More specifically, the command/address terminal 610a_5 and a via 561a_5 are connected by a wiring 501a_5 formed in the conductor layer 501a. The via 561a_5 and a via 560a_5 are connected by a wiring 710a_5 formed in the conductor layer 504a. The via 560a_5 and a via 562a_5 are connected by a wiring 710a_6 formed in the conductor layer 503a. The via 562a_5 and the command/address terminal 611a_5 of the memory device 611a are connected by a wiring 501a_6 formed in the conductor layer 501a. The angle formed between the wiring 710a_5 and the wiring 710a_6 is 90°.

Thus, the plurality of wirings 710a_1, 710a_3, and 710a_5 and the plurality of wirings 710a_2, 710a_4, and 710a_6 intersect each other at 90° in the plan view of the printed wiring board 500a viewed in the Z direction.

Here, the wiring length of Example 1 is compared with the wiring length of Comparative Example using specific examples. When the wiring length of the wiring 710a_3 of Comparative Example is 6 mm and the wiring length of the wiring 710a_4 is 2 mm, the wiring length of the wirings 710a_3 and 710a_4 of Comparative Example is 8 mm. On the other hand, the wiring length of the wiring 710_3 of Example 1 is 4 mm, the wiring length of the wiring 710_4 is 2\sqrt{ }2 mm ≈2.8 mm, and the wiring length of the wirings 710_3 and 710_4 of Example 1 is 6.8 mm. Therefore, the wiring length of Example 1 is 1.2 mm (15%) shorter than that of Comparative Example.

As described above, according to Example 1, the variation in the lengths of the wirings constituting the command/address signal wiring 710 can be suppressed to a small extent, and the wiring can be shortened.

### Example 2

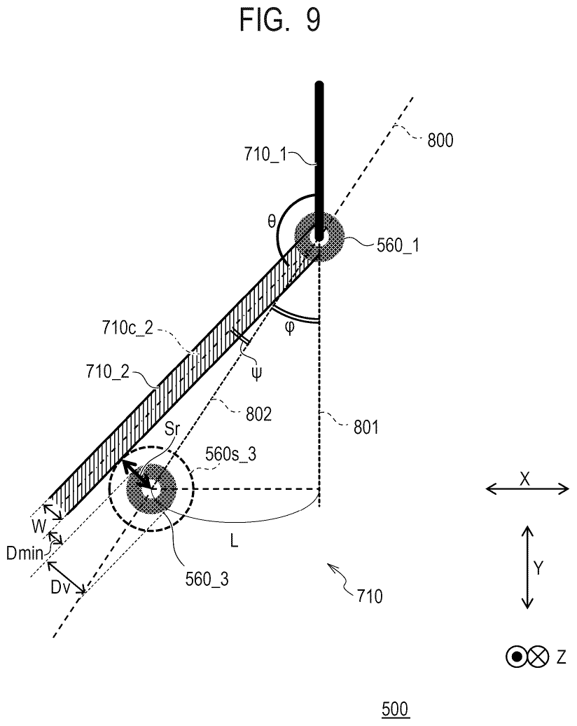

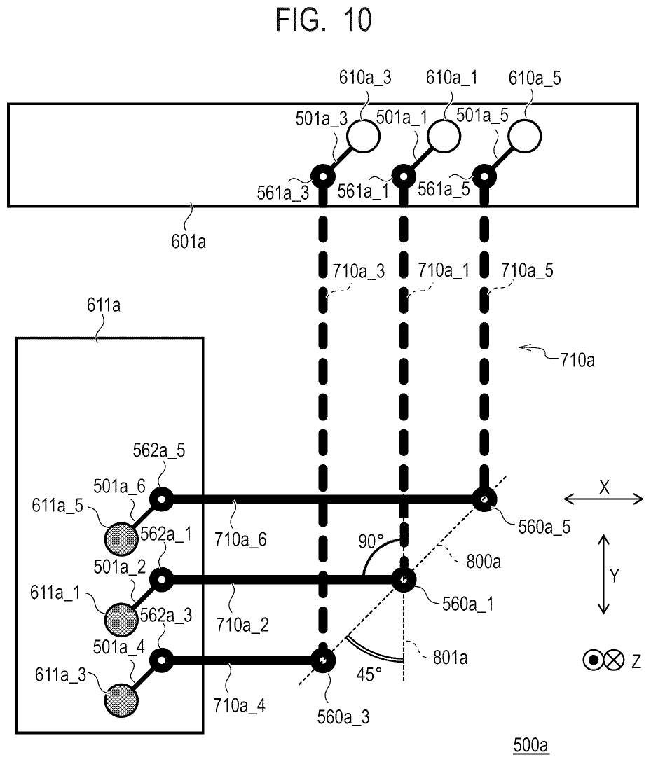

In practical use, a suitable range of the angle φ can be derived by taking into account the width of the wiring, the diameter of the via (via diameter) and the minimum distance between the wiring and the via. FIG. 9 is a plan view illustrating a case where the width of the wiring 710_2 is W and the distance 560s_3 between the wiring 710_2 and the center of the via 560_3 is Sr in a plan view viewed in the Z direction. When the distance Sr is between the center of the wiring 710_2 and the via 560_3, the angle between the line segment 802 connecting the center of the via 560_1 and the center of the via 560_3 and the center line 710c_2 of the wiring 710_2 is ψ (psi). When the minimum distance (gap) between the wiring 710_2 and the via 560_3 is represented by Dmin and the via diameter of the via 560_3 is represented by Dv, Sr=(Dv/2)+Dmin.

A condition under which the distance between the wiring 710_2 and the center of the via 560_3 is minimum is θ+φ+ψ≤180°. Therefore, it is preferable that the angles θ, φ and ψ satisfy 0+φ+ψ≤180°. The angle ψ is obtained by the following expression (4).

$$ψ = arcsin ( \frac{\frac{W}{2} + Sr}{\sqrt{{L}^{2} + {( \frac{L}{sin θ} )}^{2}}} ) \qquad ( 3 )$$

A practically suitable range of the angle φ formed by the line 800 passing through the center of via 560_1 and the center of via 560_3 (the line segment 802 connecting both of the centers) and the line 801 which overlaps the wiring 710_1 and passes through the wiring 710_1 can be estimated by taking into account the actual wiring width, the actual via diameter and the actual minimum spacing.

For example, the width W of the wiring 710_2 is 200 μm and the via diameter Dv is 250 μm. When the minimum interval Dmin between the wiring 710_2 and the via 560_3 is 100 μm, the distance Sr from the center of the via 560_3 to the end of the wiring 710_2 is 225 μm ((250 μm/2)+100 μm). When the angle θ formed between the wiring 710_1 and the wiring 710_2 is 135°, the practice al range of the angle φ is 20° or more and 50° or less, more preferably 20° or more and 35° or less. The more suitable specific angle φ is 35°. When the angle φ is 20° or more, the variation in the lengths of the wirings can be suppressed to a smaller extent and is suitable for the memory interface. When the angle φ is 35° or less, the minimum distance Sr between the wiring 710_2 and the via 560_3 can be surely satisfied.

As explained above, in the examples, when the angle θ between the wiring 710_1 and the wiring 710_2 is greater than 0° and less than 180°, the variation in the lengths of the wirings can be suppressed to a small extent and the wiring length can be shortened. Also, in the examples, the practical suitable range of the angle φ for determining the arrangement position of the vias has been clarified.

Note that the present disclosure is not limited to the above-described embodiments, and many modifications are possible within the technical concept of the present disclosure. Furthermore, the effects described in the embodiments only list the most suitable effects arising from the present disclosure, and the effects of the present disclosure are not limited to those described in the embodiments.

According to the present disclosure, it is possible to realize the increase in the speed of the memory interface.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2023-166283, filed Sep. 27, 2023, which is hereby incorporated by reference herein in its entirety.

What is claimed is:

1. A printed wiring board over which a first element having a plurality of first signal terminals and a second element having a plurality of second signal terminals are mountable, the printed wiring board comprising:
a plurality of first wirings, a plurality of second wirings, and a plurality of vias, the plurality of first wirings, the plurality of second wirings, and the plurality of vias being provided to electrically connect the plurality of first signal terminals and the plurality of second signal terminals,
wherein the plurality of first wirings and the plurality of second wirings are connected via the plurality of vias provided at intersections of the plurality of first wirings and the plurality of second wirings in a plan view viewed in a direction perpendicular to a main surface of the printed wiring board,
wherein an angle θ formed by the plurality of first wirings and the plurality of second wirings in the plan view, which is on a side closer to the first element and the second element, is greater than 90° and less than 180°, and
wherein an angle φ formed by a first straight line passing through centers of the vias adjacent to each other and a second straight line passing through the first wiring in the plan view, which is on the same side as the angle θ relative to the second straight line, is arctan(sin θ).

2. The printed wiring board according to claim 1, wherein, in the plan view, the first wiring is arranged on a side of the first element more than the second wiring with respect to the via.

3. The printed wiring board according to claim 1, wherein the angle θ, the angle φ, and an angle ψ formed by the second wiring and the first straight line in the plan view satisfy θ+φ+ψ≤180°.

4. The printed wiring board according to claim 1, wherein the angle φ is 20° or more and 50° or less.

5. The printed wiring board according to claim 1, comprising:
a surface layer over which the first element and the second element are mountable;
a first inner layer; and
a second inner layer located farther from the surface layer than the first inner layer,
wherein the first wiring is formed in the second inner layer and the second wiring is formed in the first inner layer.

6. The printed wiring board according to claim 5, comprising:
a first ground layer located farther from the first inner layer than the surface layer; and
a second ground layer located between the surface layer and the second inner layer.

7. The printed wiring board according to claim 6, comprising:
a ground via connecting the first ground layer and the second ground layer,
wherein, in the plan view, the ground via is arranged on a perpendicular bisector with respect to a line segment connecting the centers of the vias adjacent to each other.

8. A printed circuit board comprising:
a first element having a plurality of first signal terminals;
a second element having a plurality of second signal terminals; and
a printed wiring board over which the first element and the second element are mounted,
wherein the printed wiring board comprises a plurality of first wirings, a plurality of second wirings, and a plurality of vias, the plurality of first wirings, the plurality of second wirings, and the plurality of vias being electrically connecting the plurality of first signal terminals and the plurality of second signal terminals,
wherein the plurality of first wirings and the plurality of second wirings are connected via the plurality of vias provided at intersections of the plurality of first wirings and the plurality of second wirings in a plan view viewed in a direction perpendicular to a main surface of the printed wiring board,
wherein an angle θ formed by the plurality of first wirings and the plurality of second wirings in the plan view, which is on a side closer to the first element and the second element, is greater than 90° and less than 180°, and
wherein an angle φ formed by a first straight line passing through centers of the vias adjacent to each other and a second straight line passing through the first wiring in the plan view, which is on the same side as the angle θ relative to the second straight line, is arctan(sin θ).

9. The printed circuit board according to claim 8, wherein, in the plan view, the first wiring is arranged on a side of the first element more than the second wiring with respect to the via.

10. The printed circuit board according to claim 8, wherein the angle θ, the angle φ, and an angle ψ formed by the second wiring and the first straight line in the plan view satisfy θ+φ+ψ≤180°.

11. The printed circuit board according to claim 8, wherein the angle φ is 20° or more.

12. The printed circuit board according to claim 11, wherein the angle φ is 50° or less.

13. The printed circuit board according to claim 8, wherein the printed wiring board comprises:
a surface layer over which the first element and the second element are mountable;
a first inner layer; and
a second inner layer located farther from the surface layer than the first inner layer, and
wherein the first wiring is formed in the second inner layer and the second wiring is formed in the first inner layer.

14. The printed circuit board according to claim 13, wherein the printed wiring board comprises:
a first ground layer located farther from the first inner layer than the surface layer; and
a second ground layer located between the surface layer and the second inner layer.

15. The printed circuit board according to claim 14, wherein the printed wiring board comprises: a ground via connecting the first ground layer and the second ground layer, and
wherein, in the plan view, the ground via is arranged on a perpendicular bisector with respect to a line segment connecting the centers of the vias adjacent to each other.

16. The printed circuit board according to claim 8, wherein the first wiring and the second wiring are address bus wirings.

17. The printed circuit board according to claim 8, comprising: a third element having a plurality of third signal terminals,
wherein the third element is mounted over the printed wiring board,
wherein, in the plan view, the first wiring is arranged on a side of the first element more than the second wiring with respect to the via, and
wherein the printed wiring board electrically connects the plurality of first signal terminals and the plurality of third signal terminals via the plurality of first wirings.

18. The printed circuit board according to claim 8, wherein the first element is a memory controller, and
wherein the second element is a memory device.

19. Electronic equipment comprising:
a housing; and
the printed circuit board according to claim 8 arranged inside the housing.

20. An image forming apparatus comprising:
a housing;
a body unit arranged inside the housing and configured to output image data; and
the printed circuit board according to claim 8 arranged inside the housing and configured to perform image processing on the image data.
